(19) United States
(12) Patent Application Publication
(10) Pub. No.: US 2001/0029596 A1
(43) Pub. Date: Oct. 11, 2001

(54) TCM decoding device and method

(76) Inventors: Jae-Hong Kim, Seoul (KR); Jun-Jin Kong, Songnam-shi (KR)

Correspondence Address: SUGHRU, MION, ZINN, MACPEAK & SEAS, PLLC, 2100 Pennsylvania Avenue, N.W., Washington, DC, 20037-3202, US

(21) Appl. No.: 09/791,542

(22) Filed: Feb. 26, 2001

(30) Foreign Application Priority Data
Apr. 6, 2000 (KR) 2000-17963

(51) Int. Cl. H03M 13/00; H03M 13/03

(52) U.S. Cl. 714/796; 714/752

(57) ABSTRACT

A branch metric calculating device using two convolutional codes has two decoders for decoding the two convolutional codes and a branch metric calculation unit. The branch metric calculation unit determines a branch metric I by calculating the distance with respect to real number components between a signal point corresponding to an input signal and each of the other signal points on a signal constellation given according to the characteristics of an encoder for encoding outputs of the two decoders and determines a branch metric Q by calculating the distance with respect to imaginary number components between the input signal point and each of the other signal points.

### PRIORITY

This application claims priority to an application entitled “TCM Decoding Device and Method” filed in the Korean Industrial Property Office on Apr. 6, 2000 and assigned Serial No. 2000-17963, the contents of which are hereby incorporated by reference.

### BACKGROUND OF THE INVENTION

1. Field of the Invention

The present invention relates generally to a decoding device and method, and in particular, to a TCM (Trellis Coded Modulation) decoding device and method using two convolutional codes.

2. Description of the Related Art

The use of error correction codes in a digital communication system improves bit error rate (BER) performance but increases the bandwidth used. Many communication channels are band-limited or power-limited in real world situations. Error correction codes have not been used because it is impossible to increase the bandwidth of a band-limited channel and the power of a power-limited channel. In view of the foregoing, TCM, a combination of modulation and coding, has recently attracted much attention. Due to the advantage of a desired coding gain without the need for increasing transmission power or a bandwidth, TCM finds its application in various communication systems such as a phone MODEM, VSB (Vestigial-Side Band modulation), and a cable MODEM.

FIG. 1 is a block diagram of a conventional TCM encoder. In FIG. 1, an encoder 101 encodes an input information bit K2 and outputs coded bits K2′. Here, the encoder 101 is a convolutional encoder. A signal mapper 102 combines input uncoded bits K1 and the coded bits K2′ to produce a signal having a real number component (an I-channel component) and an imaginary number component (a Q-channel component). This signal is mapped to a signal point on a predetermined signal constellation. That is, the TCM code includes coded bits and uncoded bits. The coded bits determine state transition, whereas the uncoded bits determine parallel transition on a trellis diagram. The signal mapper 102 maps both the coded and uncoded bits to one signal point in the signal constellation.

A Viterbi decoder is generally used as a TCM decoder. FIG. 2 illustrates the structure of a typical Viterbi decoder. In FIG. 2, a BMC (Branch Metric Calculation) unit 201 calculates the branch metrics of all possible branches starting from a present state on a trellis diagram. An ACS (Add Compare Selector) 202 calculates the path metric values of surviving paths using the branch metrics received from the BCM unit 201, compares the path metric values, and selects an optimal path. A PM (Path Memory) 203 stores information about the selected path. A branch metric at the state transition is defined as the Euclidean distance between an input signal and a signal point in the signal constellation in a two-dimensional Euclidean space. Let the input signal be (RI, RQ) and the signal point on the signal constellation be (SI, SQ). Then, the Euclidean distance is

\sqrt{(R_{I}−S_{I})²+(R_{Q}−S_{Q})²} (1)

A square-root logic is required to implement the above equation in hardware. In a real situation, the equation is implemented using a look-up table. Alternatively, a squared Euclidean distance (R_{I}−S_{I})²+(R_{Q}−-S_{Q})² or an absolute value |R_{I}−S_{I}|+|R_{Q}−S_{Q}| can be used. Despite the advantage of higher accuracy, the squared Euclidean distance calculation increases hardware complexity.

There is another conventional TCM encoder using two convolutional codes. Referring to FIG. 3, the TCM encoder will be described. A first encoder 301 encodes an input information bit K2 and outputs coded bits K2′. A second encoder 302 encodes an input information bit K3 and outputs coded bits K3′. Here, the first and second encoders 301 and 302 are convolutional encoders. A signal mapper 303 combines uncoded bits K1, the first coded bits K2′ received from the first encoder 301, and the second coded bits K3′ received from the second encoder 302 to produce a signal with a real number component (an I-channel component) and an imaginary number component (a Q-channel component). The signal with the real and imaginary number components is mapped to one signal point in a signal constellation.

For example, 6 bits per symbol are used to map a signal in a 64-QAM (Quadrature Amplitude Modulation) signal constellation. Then, the signal mapper 303 maps four uncoded bits, one coded bit received from the first encoder 301, and one coded bit received from the second encoder 302 to one signal point in the signal constellation.

Here, the information bits K2 and K3 input to the convolutional encoders 301 and 302 operate independently and their output coded bits K2′ and K3′ are also independent of each other. In the TCM encoder, the two convolutional encoder outputs are an I-channel signal and a Q-channel signal, respectively on the signal constellation.

Hereinafter, a coded bit output from the first encoder 301 is called an I bit and a coded bit output from the second encoder 302 is called a Q bit.

FIG. 4 illustrates an example of a signal constellation when a TCM encoder using two convolutional encoders employs 64-QAM. The signal constellation varies with the characteristics of the TCM encoder. As shown in FIG. 4, coded bits (I bits and Q bits) are grouped into four sets: set 0 to set 3. The Euclidean distances between an input signal and signal points in each of set 0 (0 0), set 1 (0 1), set 2 (1 0), and set 3 (1 1) are calculated and a representative signal point with a minimum Euclidean distance is selected from each set in order to calculate a branch metric. The selected representative signals are shown in FIG. 5.

FIG. 6 is a block diagram of a TCM decoder corresponding to the TCM encoder of FIG. 3.

Referring to FIG. 6, a pruner 601 separates uncoded data and coded data from data “I”. A delay 602 delays the uncoded data for a predetermined time. A sequence estimator 603, including a Viterbi decoder, decodes the coded data received from the pruner 601. A BCC (Binary Convolutional Code) encoder 604 encodes the decoded bits. Coded bits output from the BCC, encoder 604 are used as a control signal to operate a selector 605 for selecting appropriate uncoded bits. That is, the selector 605 is a multiplexer that selects one of four possible combinations of uncoded bits received from delays 602 and 612 according to the two coded bits received from the BCC encoders 604 and 614. A combiner 606 arranges uncoded bits selected by the selector 605 and decoded bits received from the sequence estimators 603 and 613.

The decoder shown in FIG. 6 is so configured that an I-channel signal and a Q-channel signal are separated prior to input to the pruners and the coded bits of the signals are processed in the sequence estimators through the pruners. The uncoded bits of the data I and Q are separately delayed, the coded bits are encoded in the same manner as in a transmitter, and one of the delayed uncoded bits is selected based on the coded bits.

Here, each of the pruners calculates a branch metric by computing the two-dimensional Euclidean distances between an input signal and signal points on a signal constellation. Parallel transition occurs at each branch on a state diagram during TCM decoding. Here, a path with a minimum Euclidean distance is selected. In a TCM system using two convolutional encoders for an I channel and a Q channel, the convolutional encoders operate independently. When calculating a branch metric in this system, the noises of the I and Q channels influence each other in the conventional Euclidean distance calculating method, decreasing decoding accuracy. In addition, calculation of a squared Euclidean distance imposes constraints on hardware.

### SUMMARY OF THE INVENTION

It is, therefore, an object of the present invention to provide a decoding device and method in which a TCM decoder using two convolutional codes separates an input signal into an I channel component and a Q channel component and calculates their branch metrics, separately.

The above object can be achieved by providing a branch metric calculating device using two convolutional codes. The branch metric calculating device has two decoders for decoding the two convolutional codes and a branch metric calculation unit. The branch metric calculation unit determines a branch metric I by calculating the distance with respect to real number components between a signal point corresponding to an input signal and each of the other signal points on a signal constellation given according to the characteristic of an encoder required for decoding of the two decoders and determines a branch metric Q by calculating the distance with respect to imaginary number components between the input signal point and each of the other signal points.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram of a conventional TCM encoder;

FIG. 2 is a block diagram of a conventional Viterbi decoder;

FIG. 3 is a block diagram of another conventional TCM encoder using two convolutional codes;

FIG. 4 illustrates an example of set partition of 64-QAM TCM codes;

FIG. 5 illustrates distribution characteristics of I bits and Q bits in the set partition of 64-QAM TCM codes;

FIG. 6 is a block diagram of a conventional TCM decoder using two convolutional codes;

FIG. 7 is a block diagram of a TCM decoder using two convolutional codes according to an embodiment of the present invention; and

FIG. 8 is a detailed block diagram of a BMC unit shown in FIG. 7.

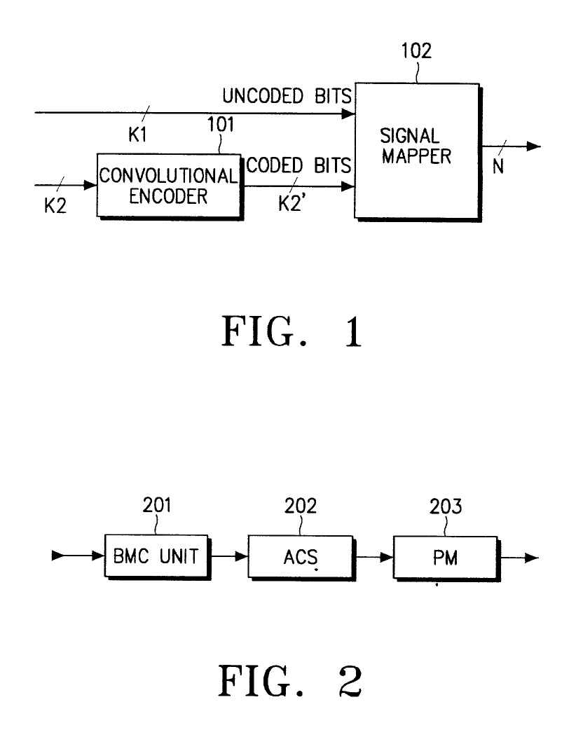

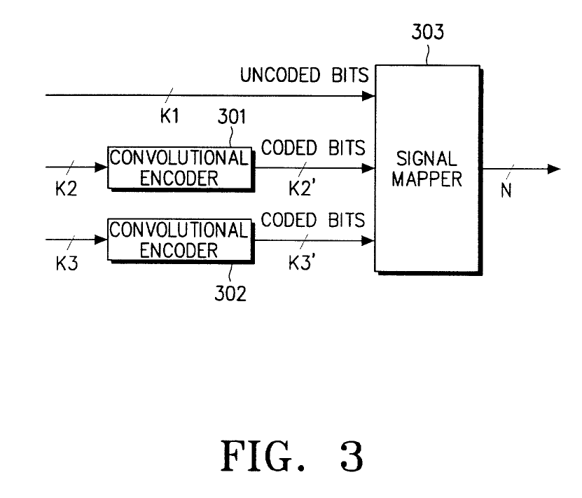

### DETAILED DESCRIPTION OF THE PREFERRED EMBODIMENT

A preferred embodiment of the present invention will be described hereinbelow with reference to the accompanying drawings. In the following description, well-known functions or constructions are not described in detail since they would obscure the invention in unnecessary detail.

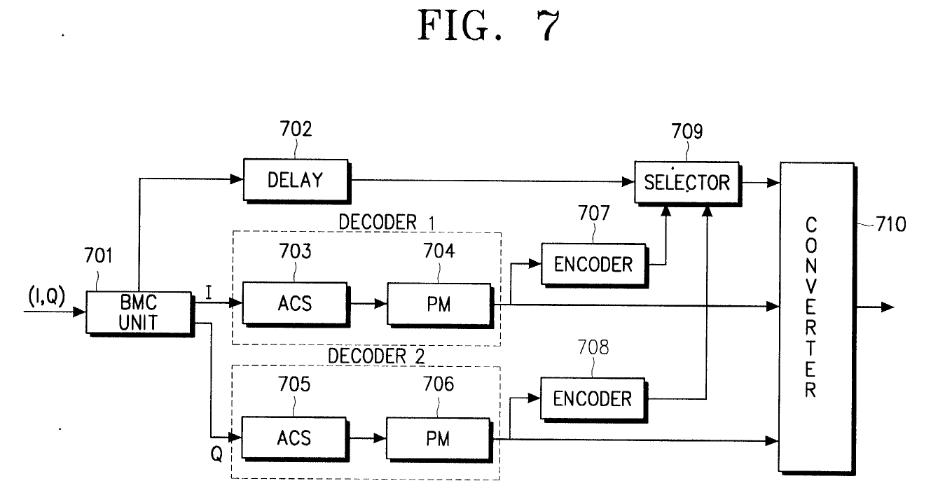

FIG. 7 is a block diagram of a TCM decoder using two convolutional codes according to an embodiment of the present invention. Referring to FIG. 7, a BMC unit 701 obtains the coordinates of an input signal on a signal constellation, separates the input signal into an I channel component and a Q channel component, calculates the distances between each channel component and signal points on the signal constellation, and outputs a branch metric I and a branch metric Q.

An ACS 703 calculates the path metrics of surviving paths in a trellis diagram with the branch metric I received from the BMC unit 701 and selects a path with the smallest path metric. A PM 704 stores the selected path and outputs a decoded information bit. Here, the ACS 703 and the PM 704 form a first Viterbi decoder for a first convolutional code. An ACS 705 calculates the path metrics of surviving paths in the trellis diagram with the branch metric Q received from the BMC unit 701 and selects a path with the smallest path metric. A PM 706 stores the selected path and outputs a decoded information bit. Here, the ACS 705 and the PM 706 form a second Viterbi decoder for a second convolutional code.

A BCC encoder 707 convolutionally encodes the information bit received from the PM 704. A BCC encoder 708 convolutionally encodes the information bit received from the path memory 706. A delay 702 delays a plurality of uncoded bits received from the BMC unit 701 for a predetermined time. A selector 709 selects one of the delayed uncoded bits received from the delay 702 based on the coded bits received from the first and second BCC encoders 707 and 708. A converter 710 arranges the information bits received from the first and second PMs 704 and 706 and the uncoded bit received from the selector 709 in a predetermined format and outputs them in series.

A feature of the present invention lies in branch metric calculation in the BMC unit 701. In implementing a TCM decoder using two convolutional codes, the branch metrics of the I and Q channels are separately calculated to thereby eliminate inter-channel interference between the I and Q channels. A branch metric is defined as a distance in a one-dimensional Euclidean space, simplifying hardware.

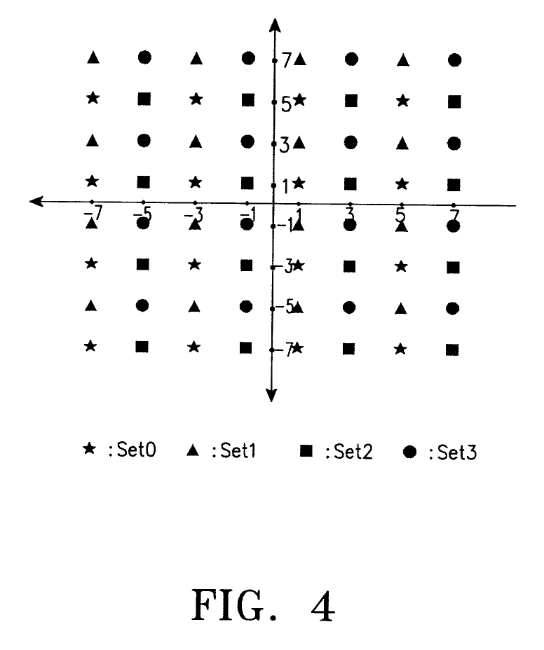

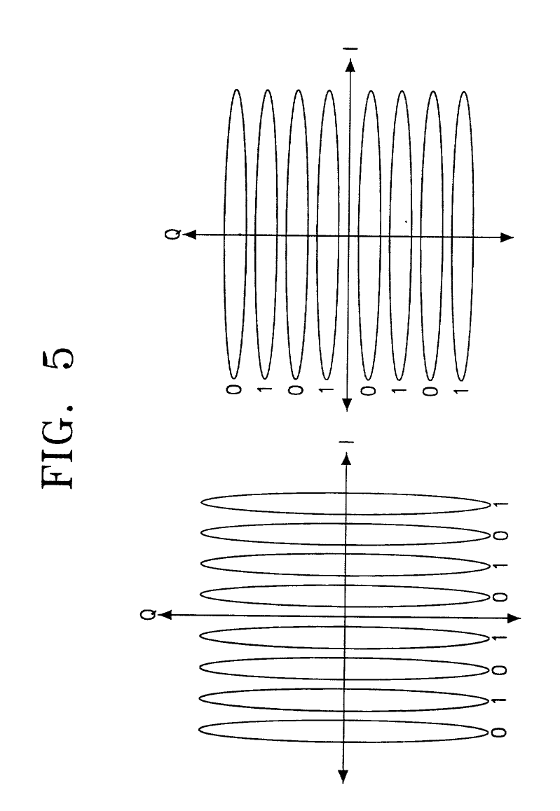

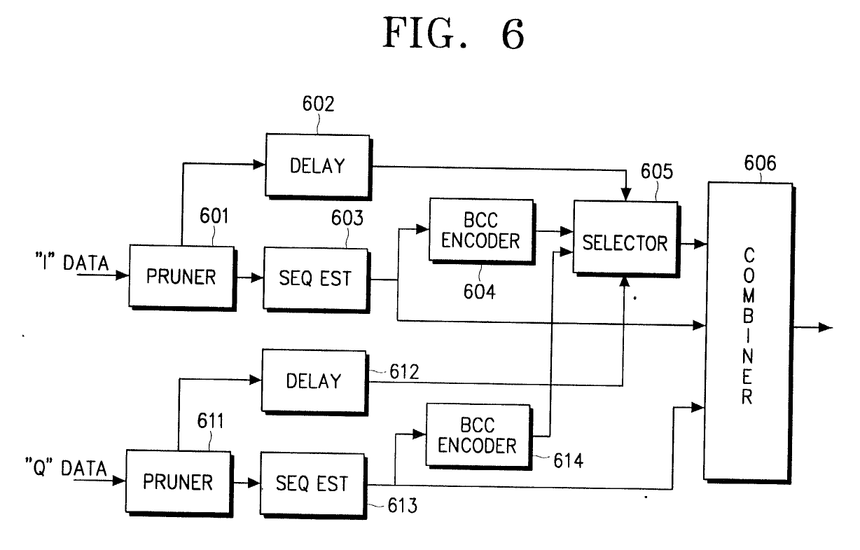

On the 64-QAM signal constellation shown in FIG. 4, a representative signal point that is the nearest to the coordinates of an input signal is selected from each set. In calculating the Euclidean distances between the coordinates of the input signal and the signal points, the branch metrics of the I and Q channels are achieved by calculating Euclidean distances along a horizontal axis for an I channel component (i.e., a real number component) and along a vertical axis for a Q channel component (i.e., an imaginary number component).

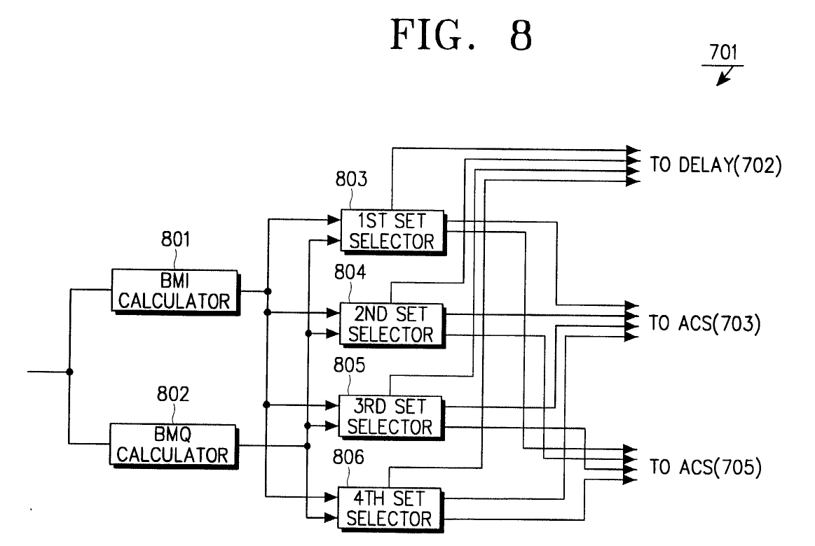

FIG. 8 is a detailed block diagram of the BMC unit 701.

Referring to FIG. 8, a BMI calculator (a first BMC) 801 calculates the distances between the coordinates of an input signal and signal points in each set only with respect to real number components and feeds the calculated distances to set selectors 803 to 806. That is, the BMI calculator 801 calculates the I-channel branch metric between the input signal and each signal point. Here, branch metrics I of set 0 are fed to the set selector 803, branch metrics I of set 1 to the set selector 804, branch metrics I of set 2 to the set selector 805, and branch metrics I of set 3 to the set selector 806.

A BMQ calculator (a second BMC) 802 calculates the distances between the coordinates of the input signal and the signal points in each set only with respect to imaginary number components and feeds the calculated distances to the set selectors 803 to 806. That is, the BMQ calculator 802 calculates the Q-channel branch metric between the input signal and each signal point. Here, branch metrics I of set 0 are fed to the set selector 803, branch metrics I of set 1 to the set selector 804, branch metrics I of set 2 to the set selector 805, and branch metrics I of set 3 to the set selector 806.

The set selectors 803 to 806 add the I-channel and Q-channel branch metrics received from the BMI and BMQ calculators 801 and 802, select representative signal points with the smallest values, and output the I-channel and Q-channel branch metrics of the representative signal points. The I-channel branch metrics are fed to the ACS 703, and the Q-channel branch metrics are fed to the ACS 705.

The operation of the TCM decoding device will be described in detail referring to FIGS. 7 and 8.

Upon receipt of a bit sequence, the BMI calculator 801 and the BMQ calculator 802 obtain the coordinates of the bit sequence, for example, on the signal constellation shown in FIG. 4, separate the input signal into an I channel component and a Q channel component, and calculate the distances between the I and Q channel components and the signal points of the signal constellation. Then, the set selectors 803 to 806 select a signal with the smallest sum of two channel branch metrics in each set and output two branch metrics BMI and BMQ of the selected signals. The set selectors 803 to 806 feed the uncoded bits of the selected signals to the delay 702. The delay 702 delays four uncoded bits received from the set selectors 803 to 806 for a predetermined time and feeds the delayed uncoded bits to the selector 709.

Meanwhile, the ACSs 703 and 705 receive the I-channel and Q-channel branch metrics BMI and BMQ and the I and Q bits of the input bit sequence from the set selectors 803 to 806, calculate path metrics of surviving paths on a trellis based on BMI and BMQ, select paths with the smallest path metrics, and inform the PMs 704 and 706 of the selected paths. Then, the PMs 704 and 706 store information about the selected paths and output decoded information bits to the BCC encoders 707 and 708 and the converter 710. The BCC encoders 707 and 708 encode the received information bits and output coded bits as a select signal to the selector 709.

Meanwhile, the selector 709 selects one of the four uncoded bits received from the delay 702 based on the select signal received from the BCC encoders 707 and 708. Then, the converter 710 arranges the decoded information bits received from the PMs 707 and 708 and the uncoded bit received from the selector 709 and outputs them in serial.

In accordance with the present invention as described above, the TCM decoding device calculates I-channel and Q-channel branch metrics separately for decoding, thereby removing interference between two channel noise. In addition, hardware complexity is decreased by calculating Euclidean distances in one-dimensional Euclidean space.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A TCM decoding device using two convolutional codes, comprising:
a branch metric calculation unit for determining a branch metric I by calculating a distance with respect to real number components between a signal point corresponding to an input signal and each of a plurality of other signal points on a signal constellation given according to encoder characteristics, determining a branch metric Q by calculating a distance with respect to imaginary number components between the input signal point and each of the plurality of other signal points, selecting a signal with a smallest sum of the two branch metrics from each signal set on the signal constellation, and delaying a plurality of uncoded bits of selected signal points by a predetermined time;
a first decoder for decoding one of the two convolutional codes using the branch metric I received from the branch metric calculation unit;
a second decoder for decoding the other convolutional code using the branch metric Q received from the branch metric calculation unit;
a first encoder for encoding decoded bits received from the first decoder;
a second encoder for encoding decoded bits received from the second decoder;
a selector for selecting one of the uncoded bits received from the branch metric calculation unit based on the coded bits received from the first and second encoders as a select signal; and
a converter for arranging the uncoded bit received from the selector and the decoded bits received from the first and second decoders in a predetermined format.

2. The TCM decoding device of claim 1, wherein the branch metric calculation unit comprises:
a first branch metric calculator (BMC) for determining the branch metric I by calculating the distance with respect to real number components between the input signal point and each of the plurality of other signal points on the signal constellation;
a second BMC for determining a branch metric Q by calculating the distance with respect to imaginary number components between the input signal point and each of the other signal points;
a plurality of set selectors for selecting a signal with the smallest sum of the two branch metrics from each of signal sets classified according to I and Q bit combinations on the signal constellation; and
a delay for delaying the uncoded bits of the selected signal points by a predetermined time.

3. The TCM decoding device of claim 1, wherein the first and second decoders are Viterbi decoders.

4. A branch metric calculating device using two convolutional codes, comprising:
two decoders for decoding the two convolutional codes; and
a branch metric calculation unit for determining a branch metric I by calculating a distance with respect to real number components between a signal point corresponding to an input signal and each of a plurality of other signal points on a signal constellation given according to the characteristics of an encoder for encoding outputs of the two decoders, and determining a branch metric Q by calculating the distance with respect to imaginary number components between the input signal point and each of the plurality of other signal points.

5. A branch metric calculating method using two convolutional codes in a branch metric calculating device which has two decoders for decoding the two convolutional codes, comprising the steps of:
determining a branch metric I by calculating a distance with respect to real number components between a signal point corresponding to an input signal and each of a plurality of other signal points on a signal constellation given according to characteristics of an encoder for encoding outputs of the two decoders; and
determining a branch metric Q by calculating a distance with respect to imaginary number components between the input signal point and each of the plurality of other signal points.

6. The branch metric calculating method of claim 5, further comprising the steps of:
selecting a signal with a smallest sum of the two branch metrics from each of a plurality of signal sets on the signal constellation;
decoding one of the two convolutional codes using the branch metric I to produce first decoded bits;
decoding the other convolutional code using the branch metric Q to produce second decoded bits;
encoding the first and second decoded bits to produce coded bits;
selecting an uncoded bit of one of the selected signal points in the signal sets based on the coded bits; and
arranging the selected uncoded bit and the decoded bits in a predetermined format.
